(19) United States
(12) Patent Application Publication
(10) Pub. No.: US 2016/0139194 A1
(43) Pub. Date: May 19, 2016

(54) REFLECTOMETRY METHOD FOR IDENTIFYING SOFT FAULTS AFFECTING A CABLE

(71) Applicant: COMMISSARIAT A L'ENERGIE ATOMIQUE ET AUX ENERGIES ALTERNATIVES, Paris (FR)

(72) Inventors: Josy COHEN, Le Plessis Trevise (FR); Nicolas GREGIS, Fresnes (FR)

(21) Appl. No.: 14/896,912

(22) PCT Filed: May 26, 2014
(86) PCT No.: PCT/EP2014/060850

§ 371 Date: Dec. 8, 2015

(30) Foreign Application Priority Data
Jun. 11, 2013 (FR) 1355377

(51) Int. Cl. G01R 31/11; G01R 31/08

(52) U.S. Cl. CPC G01R 31/11; G01R 31/088

(57) ABSTRACT

The reflectometry method for identifying at least one fault affecting a cable at at least one point, comprises: a step for estimating a parameter characteristic of the propagation of a signal within the cable, which include the attenuation α(f), the phase factor β(f), the reflection coefficient Γin(f) seen at the input of the cable from which is subtracted an estimate of the reflection coefficient in the absence of faults or a function, linear or non-linear, any of these parameters or a combination of parameters, the estimation being made as a function of the frequency of the signal based on a reflectogram of the signal, a step for transformation of the estimate of the parameter from the frequency domain into the time domain, a step for identification of the faults affecting the cable from the identification of the amplitude peaks of the estimate of the parameter transformed into the time domain.

The present invention relates to the field of diagnostic systems and methods for cables. More precisely, the invention relates to the reflectometry methods allowing the faults affecting a cable to be detected and/or localized.

The invention is applicable to any type of electrical cable, in particular cables for transmission of energy or communications cables, in fixed or mobile installations. The cables in question may be coaxial, twin-core, in parallel lines, in twisted pairs, stranded-wire cable or any other type. The invention may also be applied to mechanical cables, for example support cables for infrastructures such as a lift or a bridge.

The known methods of time-domain or frequency-domain reflectometry are particularly well suited to the detection of hard faults in a cable, such as a short circuit or an open circuit or, more generally, a significant local modification of the impedance of the cable. The detection of the fault takes place via the measurement of the amplitude of the signal reflected on this fault which has a higher amplitude, and is hence more detectable, the harder the fault.

In contrast, a soft fault, for example resulting from a surface degradation of the sheath of the cable, from rubbing or heating of the cable, generates a low amplitude peak on the reflected reflectometry signal and is consequently more difficult to detect by conventional time-domain methods.

The reflectometry method referred to as LIRA (Line Resonance Analysis) is known, such as is described for example in the article “Overview of the Halden Reactor Project Activities on Cable Aging Management and Condition Monitoring” by Paolo F. Fantoni. This method is based on the use of a test signal whose frequency is varied in order to measure the phase-shift obtained on the reflected signal as a function of the frequency variation. Using this phase-shift measurement, it is possible to detect an unexpected behavior which may be associated with a soft fault.

This method is limited to the use of frequency-domain reflectometry signals and notably has the drawback of not being usable simultaneously with the normal operation of the cable but of requiring an interruption in operation in order to perform the test.

The invention aims to provide a solution allowing the characterization of soft faults, in other words faults that lead to a less-significant local modification of the characteristic impedance of the cable.

The invention is based on the calculation of the attenuation of a signal propagating along the cable under test so as to generate a detection function in which the amplitude peaks associated with the soft faults are reinforced.

The invention notably offers the following advantages. It is compatible with time-domain, frequency-domain reflectometry methods or methods designed not to interfere with the nominal operation of the cable, such as the MCTDR (Multi-Carrier Time-Domain Reflectometry) method. It can operate in real time on measurements carried out using a signal injected into the cable then reflected but also on simulated signals. The invention can also be applied to the diagnosis of point-to-point links but also of wired networks. It is independent of the waveform of the reflectometry signal used. The invention also allows the development of a soft fault over time to be monitored.

One subject of the invention is a reflectometry method for identifying at least one fault affecting a cable at at least one point, characterized in that it comprises the following steps:
a step for estimating a parameter characteristic of the propagation of a signal propagating within said cable, amongst which are the attenuation α(f), the phase factor β(f), the reflection coefficient [symbol] ᵢₙ(f) seen at the input of the cable from which is subtracted an estimate of said reflection coefficient in the absence of faults or a function, linear or non-linear, of any one of these parameters or of a combination of several of these parameters, said estimation being made as a function of the frequency of said signal based on a reflectogram of said signal,
a step for transformation of the estimate of said parameter from the frequency domain to the time domain,
a step for identification of the faults affecting said cable from the identification of the amplitude peaks of the estimate of said parameter transformed into the time domain.

According to one particular embodiment, the method according to the invention furthermore comprises a step for detecting faults consisting in comparing the amplitude of the estimate of said parameter transformed into the time domain with at least one predetermined threshold, a fault being detected when said threshold is exceeded.

According to one particular embodiment, the method according to the invention furthermore comprises a step for localizing faults using the time abscissa of the detected amplitude peaks.

According to one particular embodiment, the method according to the invention furthermore comprises an additional step for multiplying the estimate of said parameter transformed into the time domain by said reflectogram in the time domain.

According to one particular embodiment of the invention, said parameter is equal to the attenuation α(f) or to the phase factor β(f) and the step for estimate of said parameter as a function of its frequency is carried out based on at least an estimate of the length of the cable, on the frequency transfer function H(f) of the cable and on the reflection coefficient at the output of the cable.

According to one particular embodiment of the invention, the step for estimating the attenuation α(f) of a signal as a function of its frequency is carried out by executing at least the following calculation:

$$α ( f ) = \frac{1}{2 l} ln \vert \frac{{Γ}_{s} ( f )}{H ( f )} \vert$$

with l an estimate of the length of the cable, H(f) an estimate of the frequency transfer function of the cable, and [symbol] ₛ(f) an estimate of the reflection coefficient at the output of the cable.

According to one particular embodiment of the invention, said reflectogram is in the frequency domain and the estimate of the frequency transfer function of the cable is equal to said reflectogram.

According to one particular embodiment of the invention, said parameter is equal to the propagation factor of the signal or to the phase velocity of the signal or to the input impedance.

According to one particular embodiment of the invention, said parameter is equal to the reflection coefficient [symbol] ᵢₙ(f) seen at the input of the cable, said coefficient being determined from the calculation of the frequency transfer function H(f) of the cable.

According to one particular embodiment, the method according to the invention furthermore comprises a step for injection of a signal into the cable and for measuring the reflected injected signal in order to produce said reflectogram.

Another subject of the invention is a reflectometry system comprising means designed to implement the reflectometry method according to the invention, a computer program comprising instructions for the execution of the reflectometry method according to the invention, when the program is executed by a processor, and a recording medium readable by a processor on which a program is recorded that comprises instructions for the execution of the reflectometry method according to the invention, when the program is executed by a processor.

Other features and advantages of the present invention will become more clearly apparent upon reading the description that follows in relation with the appended drawings which show:

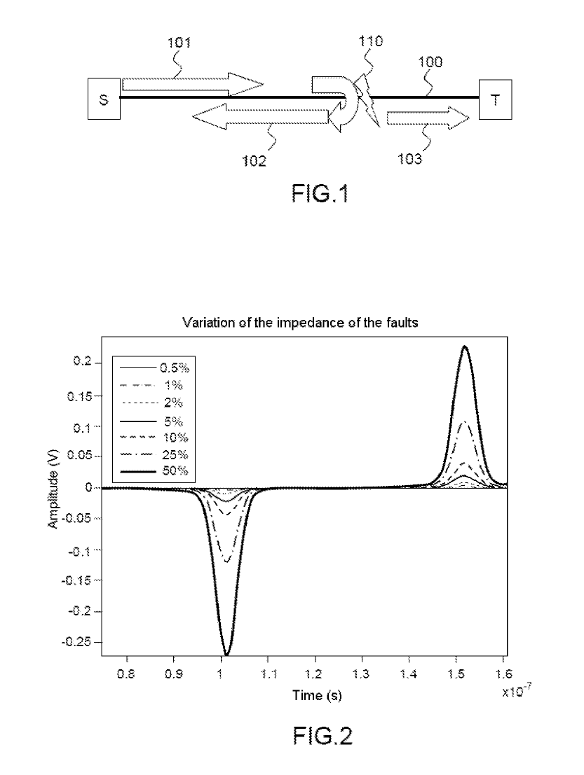

FIG. 1, a schematic overview of a reflectometry method for the detection of faults affecting a cable under test,

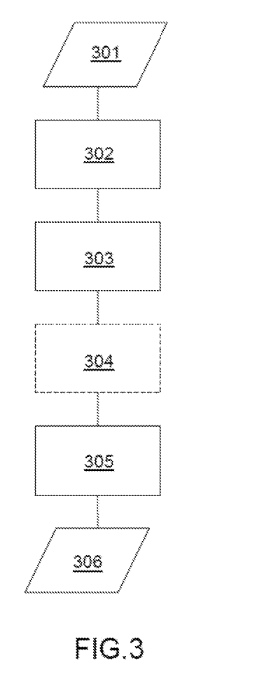

FIG. 2, a diagram of several time-domain reflectograms illustrating the difficulty for the detection of soft faults,

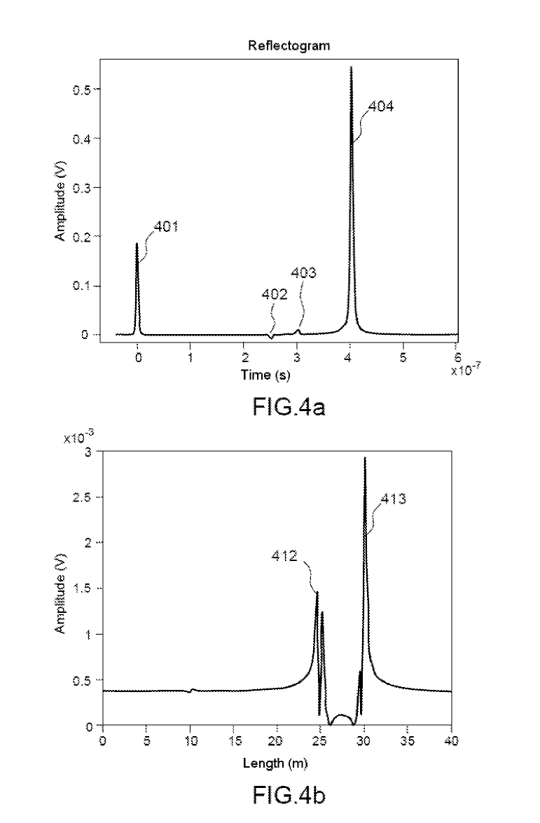

FIG. 3, a flow diagram of the steps for implementing the method for detecting soft faults according to the invention,

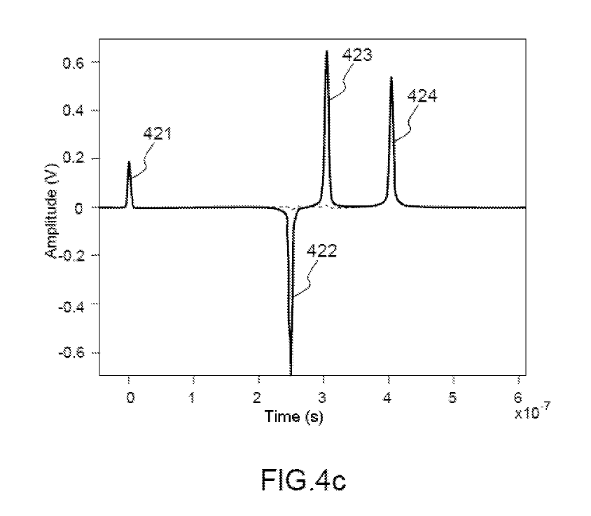

FIGS. 4a, 4b and 4c, three diagrams respectively illustrating, in one exemplary application, a reflectogram before application of the method according to the invention, a reflectogram obtained at an intermediate step of the method according to the invention and a reflectogram obtained after application of the method according to the invention,

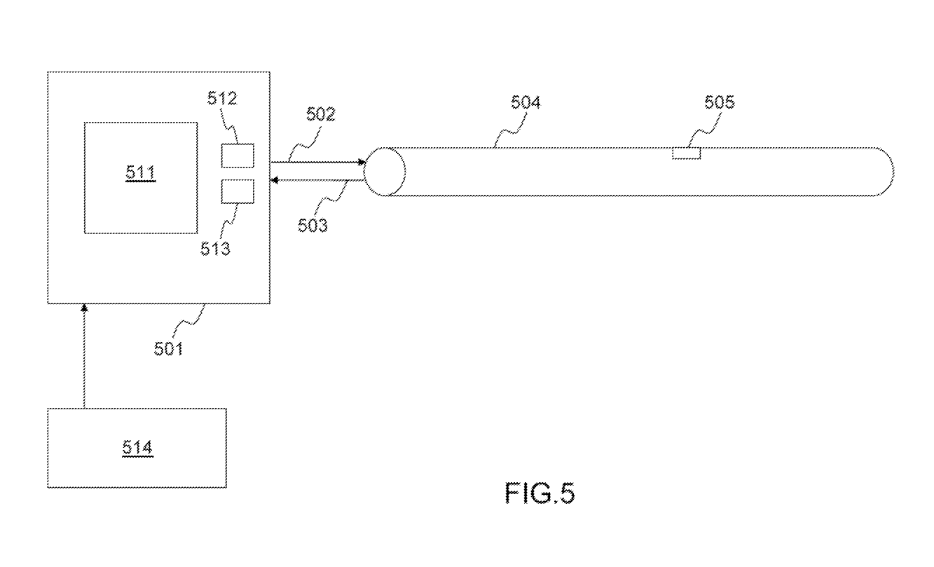

FIG. 5, a schematic diagram of a reflectometry system comprising means designed to implement the method according to the invention.

FIG. 1 shows a schematic overview of a reflectometry method for the detection of a fault affecting a cable 100.

A reflectometry system S is used to inject a test signal 101, at one point of the cable, for example at its end. The test signal 101 propagates along the cable and is reflected on a singularity 110 of the cable.

A singularity in a cable corresponds to a interruption in the conditions of propagation of the signal within this cable. It results most frequently from a fault that locally impacts the characteristic impedance of the cable causing a discontinuity in its transmission-line parameters.

A part of the signal 103 continues to propagate up to the cable end T. Another part of the signal 102 is reflected on the singularity and is propagated back to a point of acquisition which may coincide with the point of injection.

A measurement carried out on the back-propagated signal, called a reflectogram, is used to identify amplitude peaks which are associated with a fault. The delay between the injection of the signal 101 and the acquisition of the reflected signal 102, by virtue of the reflectogram, allows the distance between the point of injection and the fault to be identified.

The known reflectometry methods can be in the time domain or in the frequency domain and may use various test signals adapted to the constraints of the cable to be tester or avoiding interference with the nominal operation of the cable.

The usual reflectometry systems offer good performance characteristics for the detection of hard faults, in other words faults resulting from a short-circuit, from an open circuit, from an end of cable or from a matched load.

However, the known methods do not allow soft faults to be detected with a sufficient reliability; these are faults that result from a surface cut in the cable, from heating, from rubbing/scraping or faults which, generally speaking, do not impact the local characteristic impedance of the cable in as significant a manner as a hard fault.

FIG. 2 shows one example of a time-domain reflectogram obtained for a cable exhibiting two soft faults whose local impedance varies between 0.5% and 50% of the impedance of the cable. By analyzing the various curves, it is observed that the lower the local impedance linked to the soft fault, the lower is also the amplitude of the associated peak on the reflectogram and hence the more difficult it is to detect.

FIG. 3 shows a flow diagram representing the steps for implementing the reflectometry method according to one particular embodiment of the invention.

The invention is described according to one particular embodiment based on the calculation of the attenuation α(f) of a signal within a cable which corresponds to a reduction in the amplitude and in the energy of this signal in the course of its propagation along the cable. Without straying from the scope of the invention, other parameters may be used in place of the attenuation, such as will be described hereinafter.

The attenuation is a value, variable in frequency, connecting the amplitude of the reflected signal 102 with the amplitude of the signal injected 101 at the cable end. The attenuation is a physical quantity which is generally used to determine the length of a cable or the amplitude of the signal injected into the cable needed for it to be measurable at the output of the cable with a sufficient amplitude. Henceforth, the attenuation of a cable will be used to denote the attenuation of a signal propagating within this cable.

When the characteristics of a cable are measured, it is possible to estimate the attenuation that it generates over the useful frequency band of the injection signal. This is achieved using the transfer function H(f) of the cable. This transfer function can be directly obtained by measuring the reflectogram, when the method used is a frequency-domain reflectometry method. When a time-domain reflectometry method is used, the transfer function H(f) may be calculated as the ratio between the frequency transform of the reflected signal and the frequency transform of the injected signal. The frequency transform of a signal may, for example, be determined by means of a direct Fourier transform.

The transfer function H(f) of a point-to-point cable matched at the input, of length l and without faults, involves the reflection coefficient [symbol] s(f) on the output of the cable, the phase factor β(f) and the attenuation α(f). The transfer function H(f) may be determined by means of the following equation, well known in the field of the transmission of electrical signals within a cable.

H(f)=Γₛ(f)e^{-2 l(α(f)+jβ(f))} (1)

The attenuation α(f) may therefore be isolated using the equation (1):

$$α ( f ) = \frac{1}{2 l} ln \vert \frac{{Γ}_{s} ( f )}{H ( f )} \vert \qquad ( 2 )$$

When faults are present on the cable, the transfer function H(f) is modified by the addition of terms tᵢ(f) taking into account the transmission of the signal through the faults and also of terms [symbol] ᵢ(f) taking into account the reflection of a part of the signal on each of the faults. Assuming that the multiple reflections introduced by the presence of the faults are negligible, the transfer function takes the following form:

$$H ( f ) = {\sum }_{i}^{nb faults} {t}_{i} ( f ) {Γ}_{i} ( f ) {e}^{- 2 {l}_{i} ( α ( f ) + j β ( f ) )} + {t}_{s} ( f ) {Γ}_{s} ( f ) {e}^{- 2 l ( α ( f ) + j β ( f ) )}$$

with tₛ(f) and [symbol] ₛ(f), the respective transmission and reflection coefficients on the end of the cable.

By recalculating the attenuation with the formula of the equation (2), the following is obtained:

$$α ( f ) = {α}_{th} ( f ) - \frac{1}{2 l} ln [ \vert \frac{{\sum }_{i}^{nb faults} {t}_{i} ( f ) {Γ}_{i} ( f ) {e}^{2 ( l - {l}_{i} ) ( α ( f ) + j β ( f ) )} + {t}_{s} ( f ) {Γ}_{s} ( f )}{{Γ}_{s} ( f )} \vert ] \qquad ( 3 )$$

with αₜₕ(f) the attenuation of the cable in the absence of faults.

From the equation (3), a more general modeling of the attenuation α(f) of the cable in the presence of faults may be deduced:

$$\begin{matrix} α ( f ) = {α}_{th} ( f ) & \\ - \frac{1}{4 l} ln {\sum }_{i}^{nb faults + 1} [ {A}_{i} ( f ) + {\sum }_{k \neq i}^{nb faults + 1} {B}_{k} ( f ) cos ( 2 β ( f ) cos ( 2 β ( f ) ( {l}_{k} - {l}_{i} ) ) ] & ( 4 )\end{matrix}$$

The term (lₖ−lᵢ) corresponds to the distance between two faults.

The modeling given by the equation (4) allows it to be deduced that the attenuation of the cable in the presence of faults is equal to a sum between the theoretical attenuation of the cable in the absence of faults and a sum of oscillating terms with an amplitude that depends on the severity of the fault and on its position in the cable, and with a period depending on the distance between the fault and the cable end.

This modeling allows it to be deduced that the attenuation of the cable may be used as a function for detecting a fault by means of the detection of the frequency amplitude peaks associated with the oscillating terms of the model in the equation (4).

This observation forms the basis of the method according to the invention represented schematically by the flow diagram in FIG. 3.

Without straying from the scope of the invention, when the cable used is not matched at the input, it is possible to get back the configuration described hereinabove by matching the input impedance via any method known to those skilled in the art.

The method according to the invention receives the following input data 301: the length of the cable under test or an estimate of this length, together with an estimate of the frequency transfer function of the cable and of the reflection coefficients at the input and at the output.

According to one particular embodiment of the invention, the length of the cable may be determined by the application of a reflectometry method allowing a hard fault, for example the termination of the cable, to be localized and the speed of propagation of the signal within the cable to be estimated. A possible reflectometry method is that described in the French patent of the applicant published under the number FR 2964246 and entitled (translated into English) “Method and device for automatic measurement of the physical characteristics of a cable, in particular the speed of propagation”. Any other alternative method allowing an estimate of the length of the cable to be obtained may be used.

In a first step 302, an estimate of the attenuation of the cable is calculated as a function of the aforementioned parameters. According to one particular embodiment, this estimate is calculated by means of the equation (2). As previously indicated, the frequency transfer function of the cable may be determined, directly or indirectly, from a reflectogram measured for the cable under test. The reflectogram can be measured from the acquisition of a signal reflected in the cable. It may also be pre-calculated and saved in order to be used by the method according to the invention. It may also be obtained by simulation of the physical characteristics of a cable.

In a second step 303, a detection function for the faults affecting the cable is calculated. This detection function is equal to the inverse frequency transform of the attenuation calculated at the step 302. In other words, the attenuation calculated at the step 302 is converted from the frequency domain into the time domain. As described with the support of the equations (1) to (4), the detection function calculated exhibits amplitude peaks associated with the faults in the cable. Their identification enables the detection of these faults. The measurement of the time delay between the peak relating to the point of injection and the peak associated with a fault allows the localization of this fault and its tracking over time.

In an optional step 304, the calculated detection function is improved by a multiplication of this function with a time-domain reflectogram used for calculating the frequency transfer function.

This step 304 allows the precision of detection to be improved in the sense that it leads to the amplification of the amplitude peaks associated with the soft faults.

A detection step 305 is subsequently carried out by comparing the detection function with one or more detection thresholds. The threshold or thresholds are configured so as to allow the detection of the amplitude peaks associated with soft faults. They are also configured so as to avoid false detections on lower amplitude peaks associated with the measurement or calculation noise or with multiple reflections.

In a last step 306, the faults are identified by the amplitude peaks that exceed the detection threshold or thresholds. In particular, an estimate of the localization of the faults may be made by measuring, on the detection function, the delay between the first peak corresponding to the point of injection and the peaks associated with the faults, then by multiplying this measurement by the speed of propagation of the signal in the cable or by determining a proportionality ratio from the measured delay between the peak associated with the point of injection and the peak associated with the termination of the cable (which corresponds to a hard fault and hence to a peak of large amplitude) and from the length of the cable.

According to one particular embodiment of the invention, the calculation of the attenuation, and hence of the detection function, is not carried out over the entire length of the cable but only over a portion of the cable situated between the point of injection and a localized hard fault. Indeed, it is pointless trying to detect soft faults beyond hard faults which completely block the propagation of the signals. In order to implement this variant, an initial step for detecting a hard fault or a cable end, for example a short-circuit, an open circuit or a matched load, is carried out based on a reflectogram obtained by a known reflectometry method.

FIGS. 4a, 4b, 4c illustrate the results obtained by application of the method according to the invention for a given example that relates to a coaxial cable with an impedance of 75 ohms connected to an input with an impedance of 50 ohms and having two soft faults situated at 25 and 30 meters, with an open circuit at the end of the line. The pulsed signal injected has a width of 5 nanoseconds.

The soft faults are, for example, as a result of attaching an object made of aluminum to the cable, the exposure of the conductor of the cable, the twisting or the pinching of the latter.

FIG. 4a shows the time-domain reflectogram obtained by application of a usual reflectometry method. On this reflectogram are identified: a distinct first peak 401 at the abscissa 0 corresponding to the point of injection, a distinct second peak 404 corresponding to the end of the cable (open circuit) and two peaks of low amplitude 402, 403 corresponding to two soft faults. It can be seen that the detection of the peaks 402, 403 is not straightforward owing to their very low amplitude.

FIG. 4b shows the detection function obtained after the step 303 of the method according to the invention. The diagram in FIG. 4b shows the amplitude of the detection function as a function of the length. Using a simple proportionality ratio, the detection function may also be represented as a function of time. It may be noted in FIG. 4b that the two peaks 412, 413 associated with the soft faults are greatly amplified with respect to the conventional reflectogram in FIG. 4a. Thus, the detection function shown in FIG. 4b already allows the two soft faults to be identified.

FIG. 4c shows, on an amplitude-time diagram, the improved reflectogram obtained by multiplying the initial reflectogram in FIG. 4a with the detection function shown in FIG. 4c. The reflectogram ultimately obtained still allows the amplitude peaks 421, 424 associated with the hard faults to be identified but also those 422, 423 associated with the soft faults.

Without straying from the scope of the invention, the method may be applied in an analogous manner by replacing the attenuation of the signal with other physical parameters of the signal such as for example the phase factor 62 p(f) of the transfer function H(f). Indeed, the demonstration carried out hereinabove for the attenuation α(f) is also valid for the phase factor β(f). In other words, the phase factor, which can be obtained from the transfer function H(f), is composed of a theoretical term corresponding to the phase factor in the absence of faults and of a sum of oscillating terms corresponding to the information associated with the presence of soft faults. The method according to the invention described with the support of FIG. 3 is then applicable in an analogous manner by replacing, in the first step 302, the calculation of an estimate of the attenuation of the cable with the calculation of an estimate of the phase factor which can for example be obtained from the equation (1).

More generally, the attenuation α(f) or the phase factor β(f) may be replaced by any linear combination or any linear or non-linear function of one of these two parameters or of these two parameters together.

For example, the method according to the invention may also be applied by replacing the attenuation α(f) with the propagation factor γ(f) whose real part is the attenuation α(f) and whose imaginary part is the phase factor β(f) or by replacing the attenuation with the phase velocity Vp(f)=2 πf/β(f) which is a function of the phase factor.

In another embodiment of the invention, the method may also be applied by replacing the attenuation α(f) with the reflection coefficient [symbol] ᵢₙ(f) seen at the input of the cable which is directly equal to the transfer function H(f). In this case, it is necessary to subtract, from the measured reflection coefficient [symbol] ᵢₙ(f), an estimate of the reflection coefficient in the absence of faults.

Any linear or non-linear function of the reflection coefficient may, in an analogous manner, be used to apply the method according to the invention. For example, the input impedance of the cable is defined by the equation

$${Z}_{i n} = {Z}_{0} \cdot \frac{( 1 + Γ in ( f ) )}{( 1 - Γ in ( f ) )} ,$$

where Z₀ is the input impedance of the cable and is one example of a function of the reflection coefficient seen at the input of the cable.

FIG. 5 describes a schematic diagram of one example of a reflectometry system according to the invention.

A cable to be tested 504 has a soft fault 505 at a given distance from a cable end.

The reflectometry system 501 according to the invention comprises an electronic component 511 of the integrated circuit type, such as a programmable logic circuit, for example of the FPGA type, or microcontroller, designed to execute two functions. On the one hand, the component 511 allows a reflectometry signal s(t) for injection into the cable 504 under test to be generated. This digitally generated signal is subsequently converted via a digital-analog converter 512 then injected 502 into one end 506 of the cable. The signal s(t) propagates within the cable and is reflected on the singularity generated by the fault 505. The reflected signal is propagated back to the point of injection 506 then sensed 503, digitally converted via an analog-digital converter 513, and transmitted to the component 511. The electronic component 511 is, on the other hand, designed to execute the steps of the method according to the invention described hereinabove in order to produce, using the received signal s(t), a time-domain reflectogram which can be transmitted to a processing unit 514, of the computer, personal digital assistant or other device type for displaying the results of the measurements on a human-machine interface.

The system 501 described in FIG. 1 is one exemplary non-limiting embodiment. In particular, the two functions executed by the component 511 can be separated into two separate components or devices. The system can also operate with analog signals, and in this case the analog-digital and digital-analog converters are not required. Instead of injecting and/or measuring the reflected signal at a cable end under test, it is also possible to carry out the injection or the measurement of the reflected signal at any given point of the cable.

The reflectometry system according to the invention may also consist of portable equipment, of the touchscreen tablet or smartphone type, coupled to means of connection to a cable.

The method according to the invention may be implemented, in the electronic component 511, using hardware and/or software elements. It may notably be implemented as a computer program comprising instructions for its execution. The computer program can be recorded on a recording medium readable by a processor.

It may also be executed using a reflectogram that is simulated or obtained by external means; in this case, the electronic component 511 may be dissociated from the reflectometry system itself.

1. A reflectometry method for identifying at least one fault affecting a cable at at least one point, comprising the following steps:
a step for estimating a parameter characteristic of the propagation of a signal propagating within said cable, amongst which are the attenuation α(f), the phase factor β(f), the reflection coefficient [symbol] n(f) seen at the input of the cable from which is subtracted an estimate of said reflection coefficient in the absence of faults or a function, linear or non-linear, of the any one of these parameters or of a combination of several of these parameters, said estimation being made as a function of the frequency of said signal based on a reflectogram of said signal,
a step for transformation of the estimate of said parameter from the frequency domain into the time domain,
a step for identification of the faults affecting said cable from the identification of the amplitude peaks of the estimate of said parameter transformed into the time domain.

2. The reflectometry method as claimed in claim 1, comprising a step for detection of faults consisting in comparing the amplitude of the estimate of said parameter transformed into the time domain with at least one predetermined threshold, a fault being detected when said threshold is exceeded.

3. The reflectometry method as claimed in claim 2, comprising a step for localization of faults from the time abscissa of the detected amplitude peaks.

4. The reflectometry method as claimed in claim 1 comprising an additional step for multiplication of the estimate of said parameter transformed into the time domain by said reflectogram in the time domain.

5. The reflectometry method as claimed in claim 1, wherein said parameter is equal to the attenuation α(f) or to the phase factor β(f) and the step for estimation of said parameter as a function of its frequency is carried out at least based on an estimate of the length of the cable, on the frequency transfer function H(f) of the cable and on the reflection coefficient at the output of the cable.

6. The reflectometry method as claimed in claim 5, in which the step for estimation of the attenuation α(f) of a signal as a function of its frequency is carried out by executing at least the following calculation:
$$α ( f ) = \frac{1}{2 l} ln \vert \frac{{Γ}_{s} ( f )}{H ( f )} \vert$$
with l an estimate of the length of the cable, H(f) an estimate of the frequency transfer function of the cable, and Γs(f) an estimate of the reflection coefficient at the output of the cable.

7. The reflectometry method as claimed in claim 5, wherein said reflectogram is in the frequency domain and the estimate of the frequency transfer function of the cable is equal to said reflectogram.

8. The reflectometry method as claimed in claim 1, wherein said parameter is equal to the propagation factor of the signal or to the phase velocity of the signal or to the input impedance.

9. The reflectometry method as claimed in claim 1, wherein said parameter is equal to the reflection coefficient Γin(f) seen at the input of the cable, said coefficient being determined from the calculation of the frequency transfer function H(f) of the cable.

10. The reflectometry method as claimed in claim 1 comprising a step for injection of a signal into the cable and for measuring the reflected injected signal in order to produce said reflectogram.

11. A reflectometry system comprising means designed to implement the reflectometry method as claimed in claim 10.

12. A computer program comprising instructions for the execution of the reflectometry method as claimed in claim 1, when the program is executed by a processor.

13. A recording medium readable by a processor on which a program is recorded comprising instructions for the execution of the reflectometry method as claimed in claim 1, when the program is executed by a processor.
